(19) United States
(12) Patent Application Publication
(10) Pub. No.: US 2024/0332892 A1
(43) Pub. Date: Oct. 3, 2024

(54) SEMICONDUCTOR LASER, DISTANCE MEASUREMENT DEVICE, AND VEHICLE-MOUNTED DEVICE

(71) Applicant: SONY GROUP CORPORATION, TOKYO (JP)

(72) Inventor: TOMOKI ONO, TOKYO (JP)

(21) Appl. No.: 18/580,729

(22) PCT Filed: Mar. 8, 2022
(86) PCT No.: PCT/JP2022/010028

§ 371 Date: Jan. 19, 2024

(30) Foreign Application Priority Data
Aug. 11, 2021 (JP) 2021-131133

(51) Int. Cl. H01S 5/06; G01S 7/484; G01S 7/499; G01S 17/931; H01S 5/00

(52) U.S. Cl. CPC H01S 5/0601; G01S 7/484; G01S 7/499; G01S 17/931; H01S 5/0071; H01S 5/0615; H01S 2301/02

(57) ABSTRACT

For example, an influence of a tail in a laser pulse is reduced. A semiconductor laser includes at least two or more gain regions and at least two or more absorption regions formed on a semiconductor substrate, in which the gain regions and the absorption regions include a continuous active layer, and the gain regions and the absorption regions are alternately formed via a separation region, and from a front end surface, a first laser pulse having a first polarized light is emitted and a second laser pulse having a second polarized light is subsequently emitted, and the first polarized light and the second polarized light are orthogonal to each other.

### TECHNICAL FIELD

The present disclosure relates to a semiconductor laser, a distance measurement device, and a vehicle-mounted device.

### BACKGROUND ART

A semiconductor laser that outputs a laser pulse (see, for example, Non-Patent Document 1 below) is used as, for example, a light source in a time-of-flight measurement method (hereinafter, appropriately referred to as time of flight (ToF)). A distance sensor of the ToF method is used in various applications such as topographic measurement, structure management, autonomous navigation, defect inspection in production lines, sports, entertainment, art, and the like. A pulse width of a laser gives a measurable time resolution. Since a speed of light is constant, the pulse width of the laser contributes to a distance resolution to be measured. For example, in a case where the speed of light is 3×108 m/s, when the time resolution is 1 nanosecond, the distance resolution is 15 cm, and when the time resolution is 1 picosecond, the distance resolution is 0.15 mm.

### CITATION LIST

### Patent Document

Non-Patent Document 1: Brigitte Lanz, et. al., Optics Express 29780 (2013).

### SUMMARY OF THE INVENTION

### Problems to be Solved by the Invention

In such a field, it is desired to minimize an influence of a pulse tail (hereinafter, also appropriately referred to as tail) of a laser pulse emitted from a semiconductor laser.

An object of the present disclosure is to provide a semiconductor laser, a distance measurement device, and a vehicle-mounted device that minimize an influence of a tail of a laser pulse.

### Solutions to Problems

The present disclosure is, for example,
a semiconductor laser including
at least two or more gain regions and at least two or more absorption regions formed on a semiconductor substrate,
in which the gain regions and the absorption regions include a continuous active layer, and the gain regions and the absorption regions are alternately formed via a separation region, and
from a front end surface, a first laser pulse having a first polarized light is emitted and a second laser pulse having a second polarized light is subsequently emitted, and the first polarized light and the second polarized light are orthogonal to each other.

In addition, the present disclosure is, for example,
a distance measurement device including:
the semiconductor laser described above; and
a light separation unit,
in which the first laser pulse and the second laser pulse are separated by the light separation unit.

The present disclosure may be a vehicle-mounted device including such a distance measurement device.

### BRIEF DESCRIPTION OF DRAWINGS

FIG. 1 is a diagram for describing a semiconductor laser according to one embodiment.

FIG. 2 is a diagram to be referred to when a driving example of the semiconductor laser according to the one embodiment is described.

FIG. 3A is a diagram schematically illustrating a current to be applied to a plurality of gain regions, and FIG. 3B is a diagram schematically illustrating an example of time waveforms of a first laser pulse and a second laser pulse to be generated.

FIG. 4A is a diagram schematically illustrating the current to be applied to the plurality of gain regions, and FIG. 4B is a diagram schematically illustrating another example of the time waveforms of the first laser pulse and the second laser pulse to be generated.

FIG. 5A is a diagram schematically illustrating the current to be applied to the plurality of gain regions, and FIG. 5B is a diagram schematically illustrating another example of the time waveforms of the first laser pulse and the second laser pulse to be generated.

FIG. 6A is a diagram schematically illustrating the current to be applied to the plurality of gain regions, and FIG. 6B is a diagram schematically illustrating another example of the time waveforms of the first laser pulse and the second laser pulse to be generated.

FIG. 7A is a diagram schematically illustrating the current to be applied to the plurality of gain regions, and FIG. 7B is a diagram schematically illustrating a time waveform of the first laser pulse generated according to the applied current and separated by a polarization beam splitter.

FIG. 8A is a diagram schematically illustrating the current to be applied to the plurality of gain regions, and FIG. 8B is a diagram schematically illustrating a time waveform of the first laser pulse generated according to the applied current and separated by the polarization beam splitter.

FIG. 9A is a diagram schematically illustrating the current to be applied to the plurality of gain regions, and FIG. 9B is a diagram schematically illustrating a time waveform of the first laser pulse generated according to the applied current and separated by the polarization beam splitter.

FIG. 10 is a diagram for describing a general Q-switched laser.

FIG. 11A is a diagram schematically illustrating a current to be applied to a plurality of gain regions of the Q-switched laser having a general configuration, and FIG. 11B is a diagram schematically illustrating a time waveform of a laser pulse generated according to the applied current.

FIG. 12A is a diagram schematically illustrating the current to be applied to the plurality of gain regions of the Q-switched laser having the general configuration, and FIG. 12B is a diagram schematically illustrating the time waveform of the laser pulse generated according to the applied current.

FIG. 13A is a diagram schematically illustrating the current to be applied to the plurality of gain regions of the Q-switched laser having the general configuration, and FIG. 13B is a diagram schematically illustrating the time waveform of the laser pulse generated according to the applied current.

FIG. 14A is a diagram schematically illustrating behavior in a resonator before and after Q switching in a general semiconductor laser, and FIG. 14B is a diagram schematically illustrating optical intensity in the resonator.

FIG. 15 is a diagram schematically illustrating behavior in the resonator of a laser pulse in the general semiconductor laser.

FIG. 16A is a diagram schematically illustrating behavior in a resonator before and after Q switching in the semiconductor laser according to the one embodiment, and FIG. 16B is a diagram schematically illustrating optical intensity in the resonator.

FIG. 17 is a diagram for describing a relationship between the first laser pulse and the second laser pulse according to the one embodiment.

FIGS. 18A to 18D are diagrams for describing specific configuration examples of the semiconductor laser according to the one embodiment.

FIG. 19 is a diagram illustrating an example of a layer structure and a lateral mode in a vertical direction of the semiconductor laser according to the one embodiment.

FIG. 20 is a diagram for describing that light confinement in the vertical direction by a refractive index distribution of a semiconductor layer structure is designed in consideration of propagation from the gain region to an absorption region.

FIG. 21 is a diagram for describing an example in which a graded structure is introduced only to a first guide layer according to the one embodiment.

FIG. 22 is a diagram for describing an example in which the graded structure is introduced to the first guide layer and a second guide layer according to the one embodiment.

FIG. 23 is a block diagram illustrating a specific configuration example of a distance measurement system according to the one embodiment.

FIG. 24 is a diagram for describing an application example.

FIG. 25 is a diagram for describing an application example.

FIG. 26 is a diagram for describing an application example.

FIG. 27 is a diagram for describing an application example.

FIG. 28 is a block diagram illustrating an example of a schematic configuration of a vehicle control system.

FIG. 29 is an explanatory diagram illustrating an example of installation positions of an outside-vehicle information detecting section and an imaging section.

### MODE FOR CARRYING OUT THE INVENTION

Hereinafter, an embodiment and the like of the present disclosure will be described with reference to the drawings. Incidentally, the description will be given in the following order.

### Background of Present Disclosure

### One Embodiment

### Modifications

The embodiment and the like to be described below are preferred specific examples of the present disclosure, and the content of the present disclosure is not limited to the embodiment and the like. Incidentally, unless otherwise specified, patterns such as color shading, hatching, and the like in the drawings do not have a specific meaning. In addition, in consideration of convenience of description, there may also be a case where illustration is appropriately simplified, or only part of configurations is denoted by a reference sign.

### Background of Present Disclosure

First, a background of the present disclosure will be described in order to facilitate understanding of the present disclosure. As described above, for example, a semiconductor laser is used for a distance sensor of a ToF method. A semiconductor laser that outputs a laser pulse of several nanoseconds has a uniform active layer in a resonator, and is obtained by applying a pulse current of several nanoseconds. This is because a response speed of a semiconductor switch and a carrier lifetime in the active layer of the semiconductor laser are sub-nanoseconds to several nanoseconds.

A semiconductor laser that outputs a laser pulse of about 100 picoseconds includes a region in which an absorption amount changes passively or actively in a resonator. Before laser oscillation, absorption in the resonator exceeds a gain, so that laser oscillation does not occur, and a carrier density of an active layer is higher than that in continuous oscillation (hereinafter, also appropriately referred to as continuous wave (CW)). When the absorption decreases, laser oscillation rapidly occurs, and a gain higher than that in the CW is instantaneously obtained, so that a pulsed laser having a high peak value is obtained.

For example, in a structure reported in Non-Patent Document 1 described above, an absorption region of 20 μm or 40 μm is provided in front of a resonator having a resonator length of 1.4 mm and a stripe width of 128 μm. A pulse current having a full width at half maximum of 1.46 nanoseconds is applied, a laser pulse is obtained around a point where a current peak is exceeded, and then a tail of about 25% of the laser pulse is generated with gradual attenuation of the pulse current. In addition, when a current value is decreased, an oscillation timing of the laser pulse is delayed, the tail is decreased, and laser pulse oscillation is also stopped.

A conventional semiconductor laser that generates a laser pulse having a high peak value as described above has a problem that a pulse tail is easily generated. In addition, there is a problem that, in order to suppress the pulse tail, it is necessary to control a pulse current with high accuracy, and a system becomes complicated. In view of such points, one embodiment of the present disclosure will be described in detail.

### One Embodiment

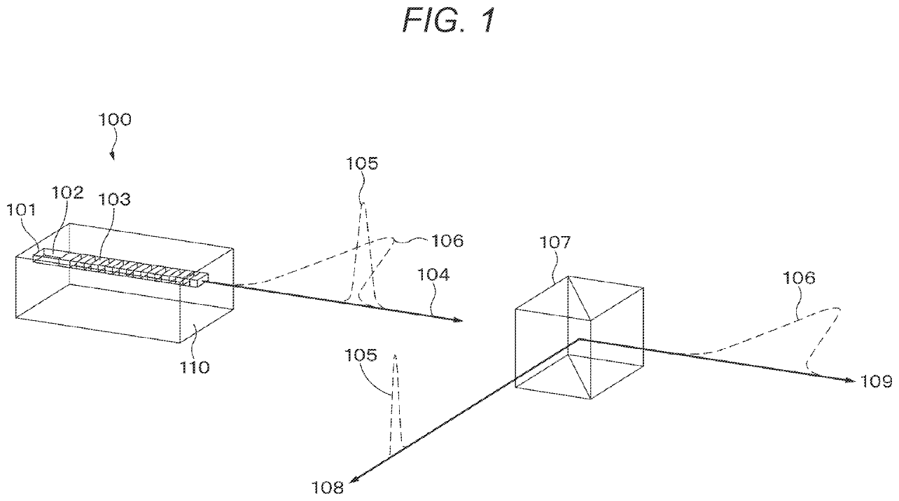

An outline of a semiconductor laser according to the present embodiment will be described with reference to FIG. 1. The semiconductor laser according to the present embodiment is, for example, a Q-switched semiconductor laser (hereinafter, appropriately abbreviated as a semiconductor laser 100).

First, the Q-switched semiconductor laser (hereinafter, also appropriately referred to as a Q-switched laser) will be schematically described. The Q-switched laser performs laser oscillation by continuing excitation while suppressing oscillation by increasing an optical loss of a laser resonator, and rapidly decreasing the optical loss of the resonator when the number of carriers in an excitation state in a laser medium becomes sufficiently large. That is, a Q-value of the resonator is instantaneously increased, so that high-intensity pulsed light can be obtained.

A Q-switch method includes a passive type that uses a saturable absorber and an active type that actively controls an absorption rate. A passive Q-switched laser has an advantage that it can be manufactured with a configuration having a relatively simple structure, but has disadvantages that self-excited vibration is likely to remain in pulsed light, and intensity is not sufficiently increased because a timing of generation of the pulsed light cannot be actively controlled. On the other hand, in an active Q-switched laser, a generation timing of pulsed light can be actively controlled, so that it is possible to compensate for the disadvantage of the passive Q-switched laser. However, since a device configuration including a driving circuit becomes complicated, there are disadvantages in terms of controllability, a size, and a cost thereof. Therefore, it is desired to appropriately set a circuit configuration in view of these points.

In the Q-switched laser, a light absorption region is provided in a resonator formed by opposing end surfaces formed by cleavage or the like. When a voltage is applied in a forward direction to a PN junction of the Q-switched laser, a forward current flows and spontaneous emission light is obtained. Since a refractive index of an active layer is higher than a refractive index of a cladding layer, light is confined in a vertical direction in the vicinity including the active layer, and is confined in a horizontal direction in the vicinity including a lower portion of a ridge by a ridge structure, and a propagation mode of the light thus confined reciprocates in the resonator having both end surfaces of the ridge structure as mirrors. At this time, the light induces light emission transitions of other electrons in an excitation state, and causes stimulated emission. The number of photons is amplified during the reciprocation in the resonator, and when the gain exceeds a loss, laser oscillation occurs.

When a reverse voltage is applied to the PN junction of the Q-switched laser, light absorption increases in the active layer. At this time, photovoltaic power is generated at the PN junction, and a photovoltaic current flows in a reverse direction. In the Q-switched laser, a property of light absorption generated by application of a reverse bias is used as Q switching.

A light absorption characteristic of the light absorption region under the application of the reverse bias depends on various factors. Light absorption increases due to a decrease in a band gap of the active layer (for example, a quantum well), an increase in a tunneling probability from the quantum well to an adjacent layer, and the like. On the other hand, since carrier densities of a p layer and an n layer are increased by photoexcitation, in a case where an anode and a cathode are not connected, a potential difference applied to the PN junction by a photocarrier decreases, and absorption decreases. Therefore, the decrease in absorption can be suppressed by connecting the anode and the cathode. In addition, when a resistor is inserted into a closed circuit between the anode and the cathode, a potential difference applied to the PN junction due to a voltage drop can be reduced. In addition, when a time constant of the closed circuit is increased, the photovoltaic current can be suppressed. A structure in which the light absorption characteristic of the light absorption region is transiently changed by light generated in a gain region is generally called the passive type. On the other hand, in the active type, the light absorption characteristic of the light absorption region is directly modulated by the driving circuit. This concludes the schematic description of the Q-switched laser.

### Configuration Example of Semiconductor Laser

As illustrated in FIG. 1, the semiconductor laser 100 includes a waveguide (optical waveguide) 101. The waveguide 101 is formed by a layer structure (semiconductor layer) epitaxially grown on a semiconductor substrate and a ridge structure provided from a side of a front surface of the semiconductor layer. In the waveguide 101, at least two or more (a plurality of) gain regions 102 and at least two or more (a plurality of) absorption regions 103 formed on the semiconductor substrate are alternately arranged and formed via a separation region as described later. When a layer structure and a driving condition as described later are satisfied, a first laser pulse 105 and then a second laser pulse 106 as a pulse tail are emitted from a front end surface 110 of the semiconductor laser 100 along an optical axis 104. Polarized light of the first laser pulse 105 (an example of first polarized light) is in a transverse magnetic (TM) mode perpendicular to a semiconductor layer structure, and polarized light of the second laser pulse 106 (an example of second polarized light) is in a transverse electric (TE) mode parallel to a semiconductor stacked structure. That is, the first polarized light and the second polarized light are orthogonal to each other.

Laser light emitted from semiconductor laser 100 passes through a collimating lens not depicted in the figures or the like, then is separated into the first laser pulse 105 and the second laser pulse 106 by a polarization beam splitter 107 as an example of a light separation unit, and becomes the first laser pulse 105 on an optical axis 108 and the second laser pulse 106 on an optical axis 109, respectively.

### Driving Example of Semiconductor Laser 100

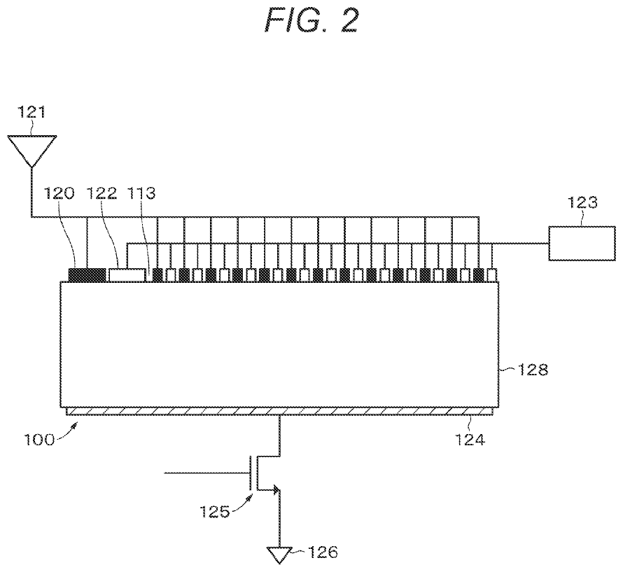

Next, a driving example of the semiconductor laser 100 will be described with reference to FIG. 2. As illustrated in FIG. 2, anode electrodes 120 (indicated by black in FIG. 2) of the plurality of gain regions 102 are connected to each other, and each anode electrode 120 is connected to a constant voltage source 121. Anode electrodes 122 of the plurality of absorption regions 103 are connected to each other and connected to a Q-switching circuit 123. The Q-switching circuit 123 is a circuit that controls a Q-switching operation, and a known circuit configuration can be applied.

A cathode electrode 124 provided to a semiconductor substrate 128 of the semiconductor laser 100 is connected to a ground 126 via a switching element 125 such as a negative-channel metal oxide semiconductor (NMOS) or the like. A cathode voltage Vcathode while the switching element 125 is off (while the NMOS is closed) is a value obtained by subtracting a voltage Vbg corresponding to band gap energy of a PN junction of the semiconductor laser 100 from a voltage Vgain of the constant voltage source 121. When the switching element 125 is turned on (when the NMOS is opened), the cathode voltage rapidly drops, and a pulse current is applied to each of the plurality of gain regions 102.

Here, a voltage Vqsw of the anode electrodes 122 of the plurality of absorption regions 103 while the NMOS is closed is lower than the voltage Vcathode, and therefore, a reverse bias is applied to PN junctions of the plurality of absorption regions 103. An active layer of the plurality of absorption regions 103 partially or entirely overlaps depletion layers formed at the PN junctions, and an absorption coefficient increases. There are capacitance and parasitic capacitance due to the PN junctions between the anode electrodes 122 and the cathode electrode 124, and capacitance can be intentionally added. When the NMOS is opened, the cathode voltage Vcathode rapidly drops, and the voltage Vqsw of the anode electrodes 122 also rapidly drops via these kinds of capacitance. Thereafter, the voltage Vqsw rapidly increases, the reverse bias of the plurality of absorption regions 103 is eliminated, and the absorption coefficient rapidly decreases. Such fluctuation of the voltage Vqsw of the anode electrodes 122 may be a self-generating method using a voltage drop in conjunction with a voltage change of the cathode electrode 124 or an active method in conjunction with a switching timing of the NMOS.

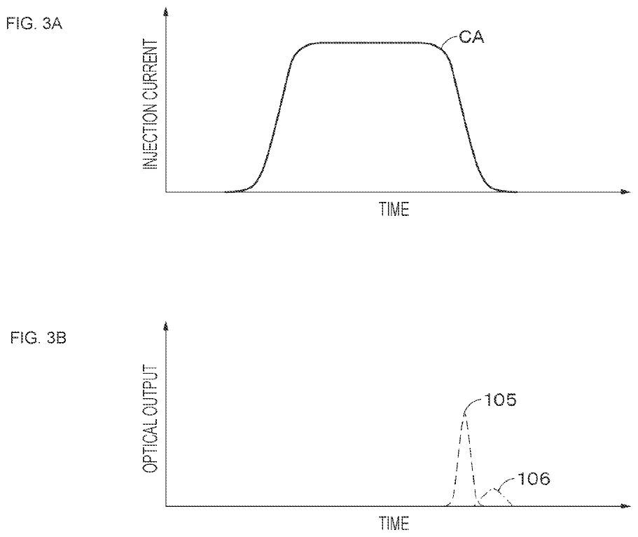

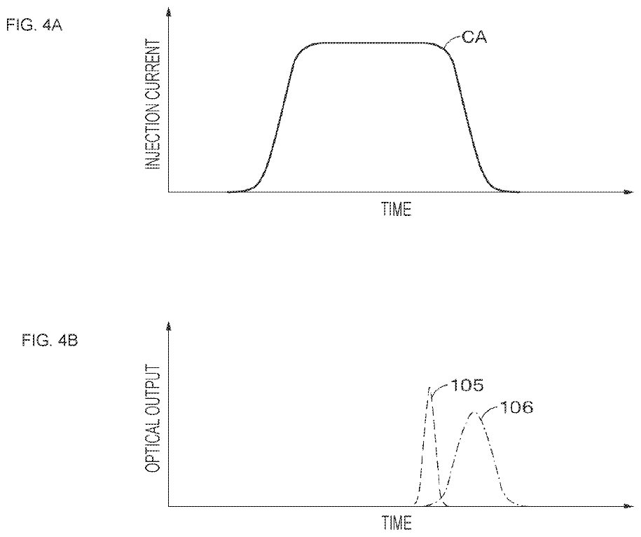

FIG. 3A illustrates a current to be applied to the plurality of gain regions 102, and FIG. 3B is a diagram illustrating simplified time waveforms of the first laser pulse 105 and the second laser pulse 106 to be generated according to the current. In FIG. 3A, a horizontal axis represents a time, and a vertical axis represents magnitude of an injection current. In addition, in FIG. 3B, a horizontal axis represents a time, and a vertical axis represents magnitude of optical output. This similarly applies to contents illustrated in each of FIGS. 4 to 6.

A pulse current CA has a carrier density saturation time longer than that of an active layer of the gain regions 102, and a pulse width of about 2 nanoseconds to 4 nanoseconds. Carrier density saturation of the active layer in the Q-switched laser is limited by ASE (amplification of spontaneous emission light). As in the present embodiment, by alternately arranging the plurality of gain regions 102 and the absorption regions 103, the spontaneous emission light generated in the gain region 102 is quickly absorbed by the adjacent absorption region 103. As a result, saturation of the carrier density due to stimulated emission using the spontaneous emission light as a seed is suppressed. That is, the carrier density saturation time becomes long.

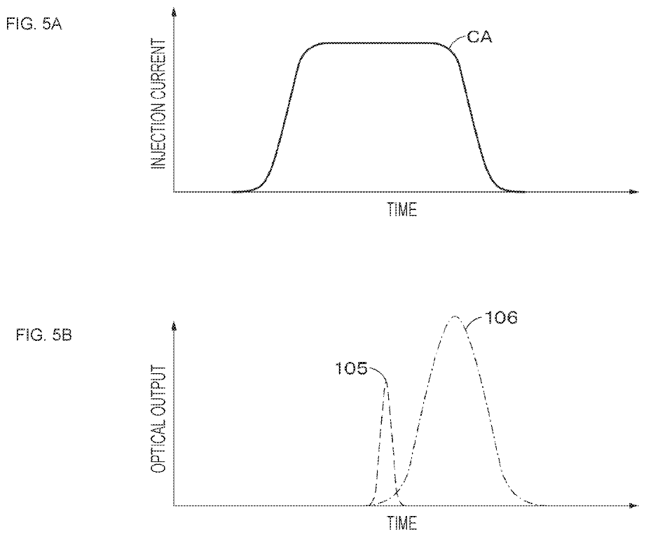

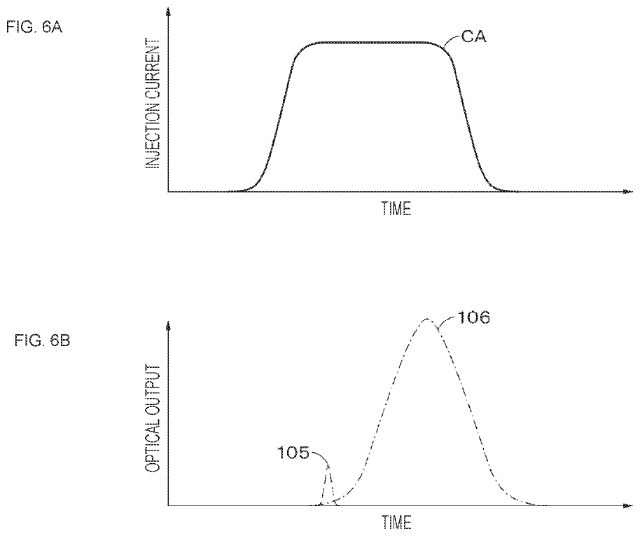

As illustrated in FIGS. 3A and 3B, when a timing of Q switching is delayed to the limit, the second laser pulse 106 is slightly generated after the first laser pulse 105 is generated. The injection current starts to decrease at such a timing due to an influence of an electrical time constant. As illustrated in FIGS. 4A and 4B, when the timing of the Q switching is advanced, a peak value of the first laser pulse 105 increases and an optical output of the second laser pulse 106 also becomes strong. As illustrated in FIGS. 5A and 5B, when the timing of the Q switching is further advanced, the peak value of the first laser pulse 105 slightly increases, while the optical output of the second laser pulse 106 becomes remarkably strong. As illustrated in FIGS. 6A and 6B, when the timing of the Q switching is further advanced, a current injection time becomes sufficiently shorter than the carrier density saturation time of the gain regions 102, and an optical output of the first laser pulse 105 becomes weak.

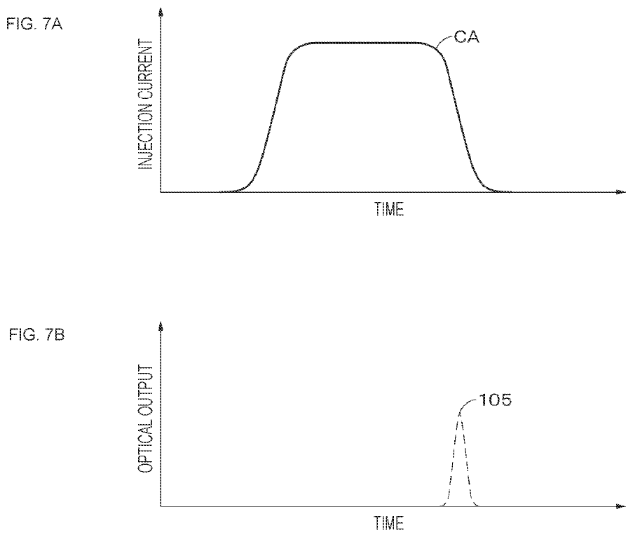

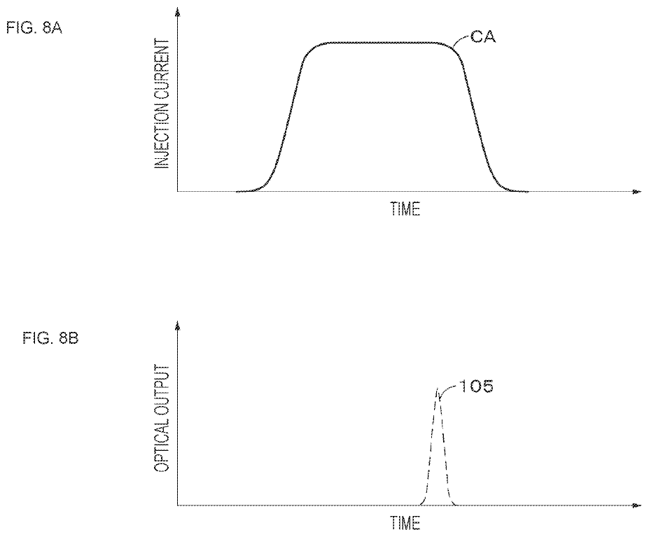

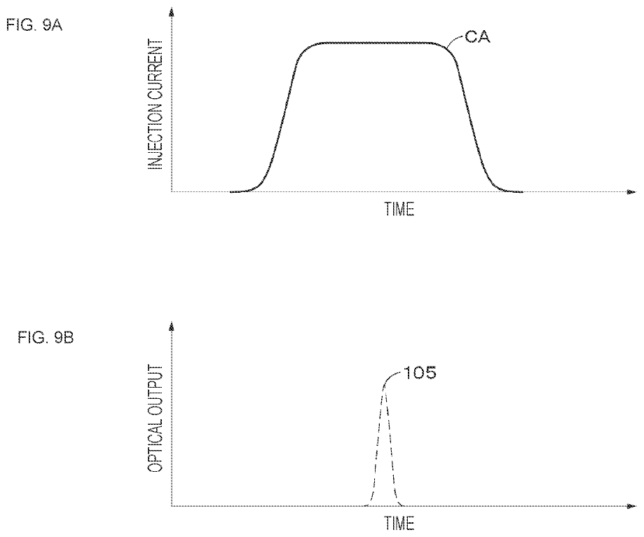

FIG. 7A illustrates the pulse current CA to be applied to the plurality of gain regions 102, and FIG. 7B is illustrates a simplified time waveform of the first laser pulse 105 generated in a case where the pulse current CA is applied and separated by the polarization beam splitter 107. This similarly applies to FIGS. 8A and 8B, and FIGS. 9A and 9B.

As illustrated in FIGS. 7A and 7B (similarly applies to FIGS. 8A and 8B and FIGS. 9A and 9B), when the timing of the Q switching is appropriate, the first laser pulse 105 having no pulse tail and a high peak value is generated in a wide time range.

### Advantages of Present Embodiment

Advantages of the semiconductor laser 100 of the present embodiment will be described in comparison with a Q-switched laser having a general configuration.

FIG. 10 illustrates an outline of the Q-switched laser having the general configuration (hereinafter, appropriately referred to as a semiconductor laser 200). The semiconductor laser 200 has a gain region 202 formed in a waveguide 201, and an absorption region 203 provided on a front surface. A laser pulse 205 is emitted from a front end surface 207 along an optical axis 204. The laser pulse 205 is accompanied by a tail 206, and both the laser pulse 205 and the tail 206 are the same polarized light. In the illustrated example, the polarized light is in the TE mode.

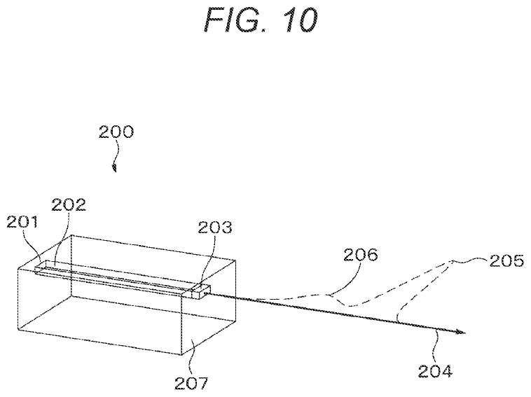

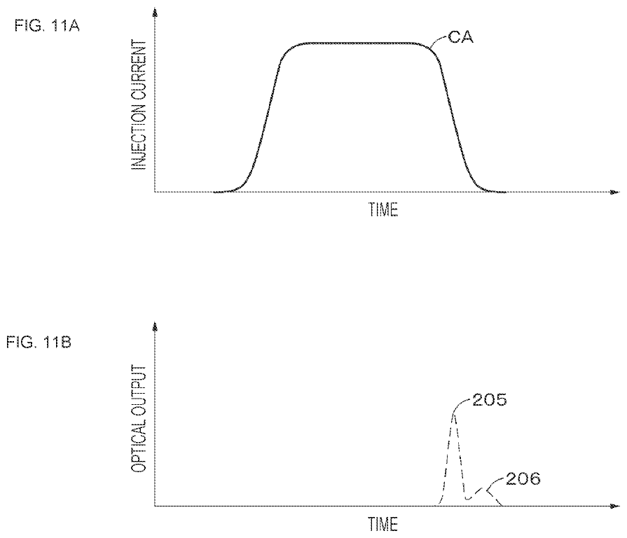

FIGS. 11A and 11B are diagrams illustrating a pulse current CA to be applied to the gain region 202, and a simplified time waveform of the laser pulse 205 and the tail 206. As illustrated in FIG. 11A, when a timing of Q switching is delayed to the limit, the laser pulse 205 is generated with the slight tail 206 as illustrated in FIG. 11B. An injection current starts to decrease at such a timing due to an influence of an electrical time constant. As illustrated in FIGS. 12A and 12B, when the timing of the Q switching is advanced, a peak value of the laser pulse 205 increases and the tail 206 also becomes strong. As illustrated in FIGS. 13A and 13B, when the timing of the Q switching is further advanced, the peak value of the laser pulse 205 slightly increases, while an optical output of the tail 206 becomes remarkably strong.

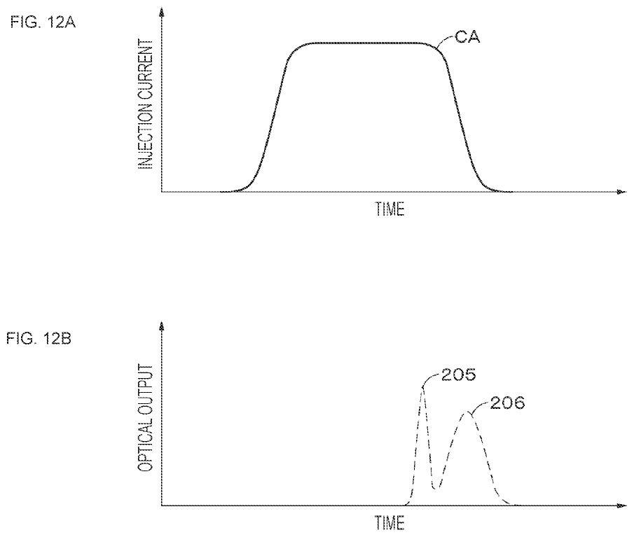

FIG. 14A is a diagram schematically illustrating behavior in a resonator before and after the Q switching in the semiconductor laser 200. FIG. 14B is a diagram schematically illustrating optical intensity in the resonator.

In the waveguide 201 of the semiconductor laser 200, the resonator is formed by a rear end surface 208 and the front end surface 207. In the waveguide 201, the gain region 202 and the absorption region 203 are provided. The absorption region 203 is provided on the front surface. In a case where a high reflection film is formed on the rear end surface 208, a backward wave generated by current injection into the gain region 202 is reflected (arrow 227) by the rear end surface 208 to become a traveling wave. On the other hand, reflection (arrow 228) of the traveling wave is suppressed by the absorption region 203 on the front end surface 207. In the gain region 202 having a significant length, for example, approximately 100 μm or more, optical intensity 230 in the resonator is maximized in the gain region 202 in the vicinity of the absorption region 203 by ASE (see FIG. 14B).

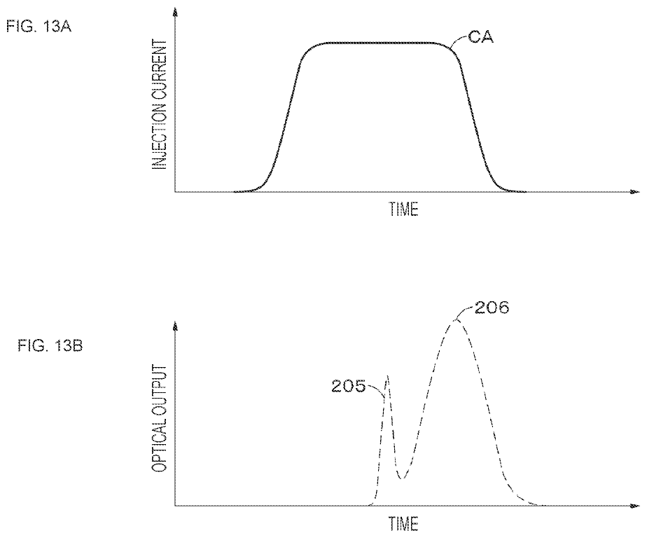

As illustrated in FIG. 15, when an absorption coefficient of the absorption region 203 decreases, resonance occurs due to reflection (arrow 240) on the front end surface 207, and laser oscillation occurs. Part of the laser pulse is coupled to the resonator by reflection, carriers injected into an active layer are not completely depleted at the time of laser pulse oscillation, and the pulse current is injected even after the laser pulse oscillation, thereby generating the tail 206. Therefore, it is considered that a time coherence remains between such a laser pulse 205 and such a tail 206.

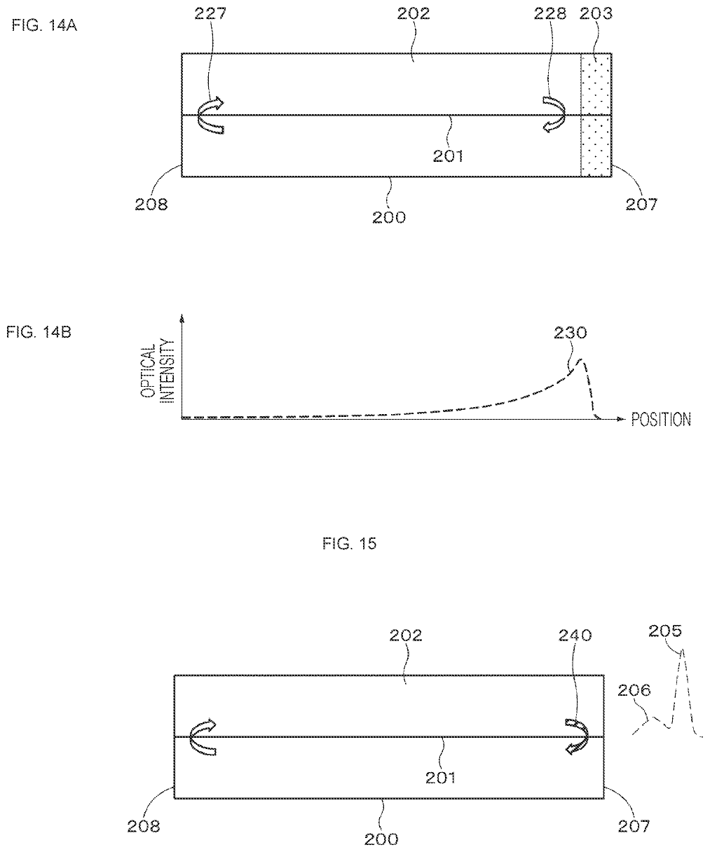

FIG. 16A is a diagram schematically illustrating behavior in the resonator before and after Q switching in the semiconductor laser 100 according to the one embodiment, and FIG. 16B is a diagram schematically illustrating optical intensity in the resonator.

The resonator is formed by a rear end surface 111 and the front end surface 110 in the waveguide 101 of the semiconductor laser 100, and the plurality of gain regions 102 and the plurality of absorption regions 103 are provided in the waveguide 101. Further, an amplification region 307 in which each of the gain regions and the absorption regions is short, and a seed region 308 constituted of a long single gain region and a long single absorption region are included. A high reflection film is formed on the rear end surface 111, and a low reflection film is formed on the front end surface 110. A length (length in the horizontal direction in FIG. 16 and length on a light propagation axis) of each gain region 102 in the amplification region 307 is 100 μm or less, and ASE is minimized. That is, most of spontaneous emission light generated in each gain region 102 is absorbed in the adjacent absorption region 103 without causing stimulated emission by ASE. A ratio of the lengths of the gain region 102 and the absorption region 103 is preferably about 1:1 to 1:0.2. In a case where the ratio of the lengths of the gain region 102 and the absorption region 103 is 1:1, the length (length in the horizontal direction in FIG. 16 and length on the light propagation axis) of each absorption region 103 in the amplification region 307 is 100 μm or less. As the gain region 102 is shorter, an influence of ASE can be suppressed, but there is a possibility that a ratio occupied by an N-type separation region 113 that electrically insulates the gain region 102 and the absorption region 103 relatively increases, or an electrode width of each region becomes narrow and disconnection by step occurs. The length of each region is appropriately determined in consideration of such a point.

On the other hand, the length of the gain region 102 in the seed region 308 is longer than the length of the gain region 102 in the amplification region 307, and may be 100 μm or more. That is, the gain region 112 in the nearest vicinity of a side of the rear end surface 111 may be longer than the other gain regions 112 in a resonator direction (on the light propagation axis). Due to reflection on the rear end surface 111, optical intensity 330 before Q switching is maximized in the gain region 102 in the vicinity of the absorption region 103 by ASE in the seed region 308 (see FIG. 16B). The seed region 308 is significantly shorter than that of the resonator of the semiconductor laser 200, and a saturation level of a carrier density before the Q switching is high. In the amplification region 307, since ASE is minimized, the saturation level of the carrier density before the Q switching is significantly high. When absorption in the absorption region 103 is decreased by the Q switching, the optical intensity 330 becomes seed light, and the first laser pulse 105 having a high peak value is generated by carriers accumulated in the amplification region 307. Thereafter, since sub-nanoseconds to several nanoseconds are required for the absorption in the absorption region 103 to recover due to an influence of various kinds of time constants, the second laser pulse 106 as the pulse tail is generated by the continuously applied pulse current CA.

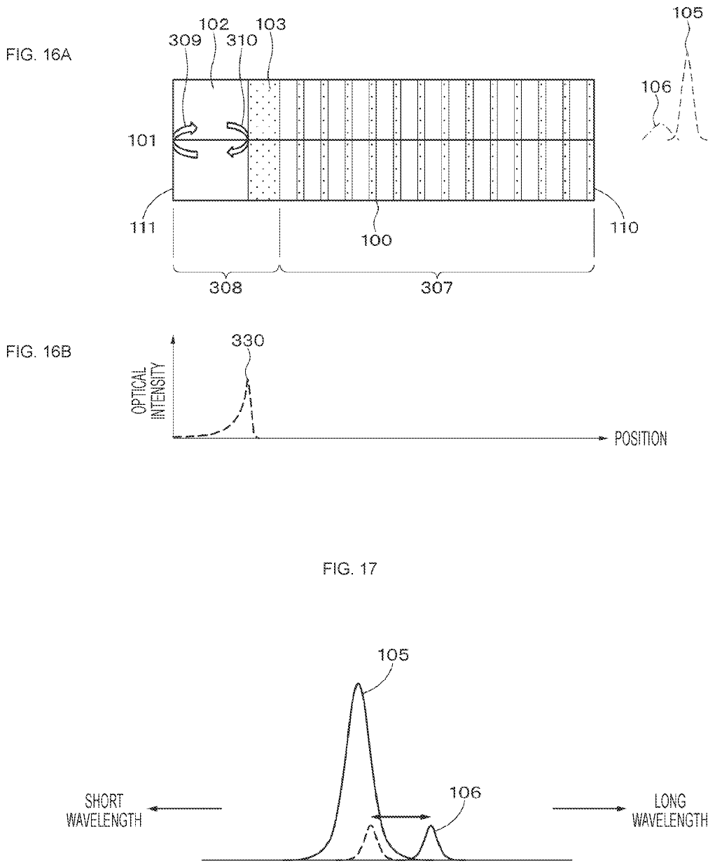

FIG. 17 is a diagram illustrating a relationship between the first laser pulse 105 and the second laser pulse 106 in the present embodiment. A peak wavelength of the first laser pulse 105 is on a longer wavelength side than a peak wavelength of the second laser pulse 106, and when a timing of inducing a Q-switching operation is delayed (when a time difference is increased), the wavelength is increased from a broken line to a solid line. The peak wavelength of the first laser pulse 105 has hopping (interval) of the peak wavelength of at least 1 nm or more than the peak wavelength of the second laser pulse 106. In a case where the wavelength becomes the longest, there may also be a case where the peak wavelength of the first laser pulse 105 is longer than the peak wavelength of the second laser pulse 106 by 5 nm or more. That is, according to the semiconductor laser 100 according to the present embodiment, the emitted first laser pulse 105 and second laser pulse 106 can be separated by appropriately controlling the timing of the Q switching.

Further, there may be a case where the increase in the peak wavelength of the first laser pulse 105 is not continuous, and is accompanied by discontinuous hopping. Such an extreme red shift is considered as Renormalization due to a many-body effect, and a band structure contributing to laser oscillation changes before and after the Q switching. As a result, it is considered that a coherence between the laser pulse and the pulse tail decreases drastically or becomes incoherent. Incidentally, in the semiconductor laser reported in Patent Document 1 described above, a stop wavelength of a laser pulse is shorter than that of a pulse tail, which is considered to be an influence of band-filling.

As a result of an experiment, for example, in the semiconductor laser 100 having an oscillation wavelength of around 830 nm using aluminum/gallium/arsenic (AlGaAs) for the active layer, both the first laser pulse 105 and the second laser pulse 106 were in the TE mode when the single active layer was 80 nm, and a center wavelength of the laser pulse was longer than that of the pulse tail by about 5 nm. Therefore, the wavelength difference for separating the laser pulse and the pulse tail by a wavelength filter is advantageous. When the single active layer was 120 nm, the first laser pulse 105 was in the TM mode, the second laser pulse 106 was in the TE mode, and the center wavelength of the first laser pulse 105 was longer than that of the second laser pulse 106. Therefore, the first laser pulse 105 and the second laser pulse 106 can be demultiplexed by the polarization beam splitter.

When the single active layer was 240 nm, both the first laser pulse 105 and the second laser pulse 106 were in the TM mode. A thickness of each active layer is longer than the Bohr radius, and a quantum effect in a stacking direction of the semiconductor layer is weak, but each active layer slightly contributes to a laser oscillation mode. Therefore, the Q-switched semiconductor laser in which the polarization of the laser pulse and the polarization of the pulse tail are different in the present embodiment is completely different from the conventional Q-switched semiconductor laser in the operation mechanism and structure. In addition, it is also completely different from mixture of TE polarized light and TM polarized light and a phase stable state for which a phenomenon is reported in low current injection in the operation mechanism and structure.

### Specific Structure Examples of Semiconductor Laser

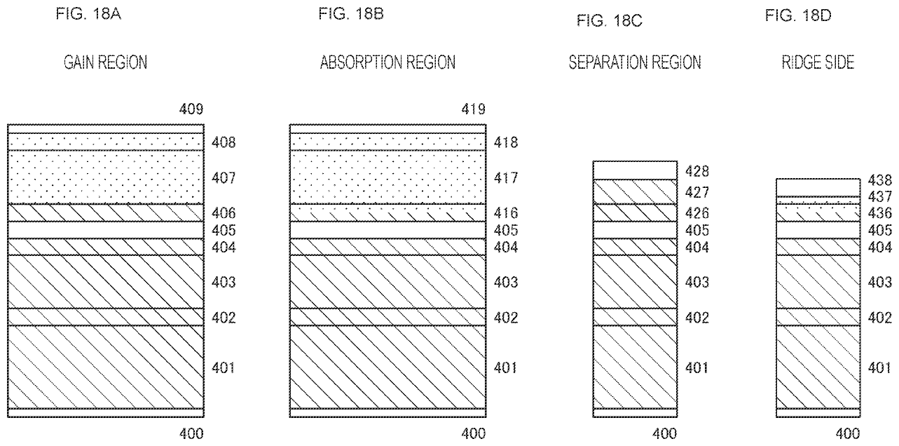

Specific structure examples of the semiconductor laser 100 according to the present embodiment will be described with reference to FIGS. 18A to 18D. FIG. 18A is a cross-sectional view illustrating a structure example of the gain region 102, FIG. 18B is a cross-sectional view illustrating a structure example of the absorption region 103, FIG. 18C is a cross-sectional view illustrating a structure example of the separation region, and FIG. 18D is a cross-sectional view illustrating a structure example of a ridge side.

A semiconductor layer formed on an n-type GaAs semiconductor substrate 401 (hereinafter, also appropriately referred to as a semiconductor substrate 401) by a semiconductor growth method such as metal organic chemical vapor deposition (MOCVD) or the like is formed by stacking an n-type AlGaAs buffer layer 402, an n-type AlGaAs first cladding layer 403, an n-type AlGaAs first guide layer 404, and an AlGaAs active layer 405 as an example of a continuous active layer. An upper portion of the active layer 405 has at least three kinds of regions and a ridge structure. The three kinds of regions are constituted of the gain region 102, the absorption region 103, and the separation region 113.

The gain region 102 is formed by stacking an n-type AlGaAs second guide layer 406, a p-type AlGaAs second cladding layer 407, and a p-type GaAs contact layer 408. The absorption region 103 is formed by stacking an AlGaAs second cladding layer 416 having a PN junction inside, a p-type AlGaAs second cladding layer 417, and a p-type GaAs contact layer 418. The separation region 113 is formed by stacking an n-type AlGaAs second guide layer 426, an n-type AlGaAs second cladding layer 427, and a dielectric film 428. Since these semiconductor layers grow simultaneously, hetero interfaces of the respective regions match.

On the other hand, positions of the PN junctions are different from each other, and a distance from the PN junction of the absorption region 103 to the active layer 405 is shorter than that of the gain region 102. In addition, in the separation region 113, there is no PN junction intentionally formed. Such a structure in which the position of the p-type semiconductor layer is different for each region can be formed by, for example, impurity diffusion or the like. However, the structure is not limited to being formed by the impurity diffusion method, but may be formed by, for example, a selective growth method, an ion implantation method, or the like.

The gain region 102 and the absorption region 103 are separated by the separation region 113, and an anode electrode 409 of the gain region 102 and an anode electrode 419 of the absorption region 103 have a PNP structure and have good electrical insulation characteristics. Therefore, since sufficient insulation can be performed even when a separation width is very narrow, it is possible to reduce a light propagation loss and improve an occupancy of the gain region 102 and the absorption region 103. A surface layer of the separation region 113 is protected by the dielectric film 428, and formation of an unintended PN junction due to a surface level or the like is suppressed. The gain region 102 and the absorption region 103 are arranged as illustrated in FIG. 2. A cathode electrode 400 common to all the regions is disposed on a back surface of the n-type GaAs semiconductor substrate 401. Incidentally, the anode electrode may be common. The second cladding layers 407, 417, and 427 and a second cladding layer 437 may include etching stop layers having a refractive index higher than that of the second cladding layers. The etching stop layer may be a single layer or a plurality of layers. These layers are used to control dry etching or wet etching when a ridge waveguide is formed.

The active layer 405 is a weak n-type with an adjusted doping concentration. The active layer 405 desirably has a single quantum well (SQW) structure. This is because, in the absorption region 103, photoexcited electron hole pairs are easily separated at the time of a reverse bias, and can be quickly moved to the cathode and anode electrodes, and overlapping of electron and hole distributions is quickly increased at the time of a Q-switching operation, and absorption saturation easily occurs. In AlGaAs having an oscillation wavelength of around 830 nm, it is preferable that the active layer 405 is a single layer and has a thickness in the range of 100 nm to 250 nm. In this range, as described above, it is easy to obtain oscillation in which the first laser pulse 105 is in the TM mode and the second laser pulse 106 is in the TE mode. This is because, in a case where the thickness is less than 100 nm, the first laser pulse 105 and the second laser pulse 106 are in the TE mode, and in a case where the thickness is greater than 250 nm, the first laser pulse 105 and the second laser pulse 106 are in the TM mode.

The waveguide 101 is formed by a refractive index distribution of the semiconductor layer structure and the ridge structure. A ridge width is desirably 8 μm to 12 μm, and a single fundamental lateral mode is obtained in both the horizontal direction and the vertical direction. Each dimension is, for example, a resonator length of 4 mm, a separation width of 4 μm, one gain region length in the amplification region 307 of 33 μm, one absorption region length in the amplification region 307 of 33 μm, a gain region length in the seed region 308 of 100 μm, and an absorption region length in the seed region 308 of 200 μm. In this example, a ratio between the gain region 102 and the absorption region 103 is 1:1. The ratio can be adjusted in a range of 0.2:1 to 1:1, but when one gain region 102 is 100 μm or more, carrier density saturation occurs due to ASE, which is undesirable. Therefore, in a case where the ratio of the absorption region 103 is small, the length of one absorption region 103 becomes short, and thus a process difficulty level increases. The front end surface 110 and the rear end surface 111 are formed by a cleaving method or a dry etching method. An anti reflection (AR) coating having a reflectance of several % or less is applied to the front end surface 110, and a high reflection (HR) coating having a reflectance of 90% or more is applied to the rear end surface 111.

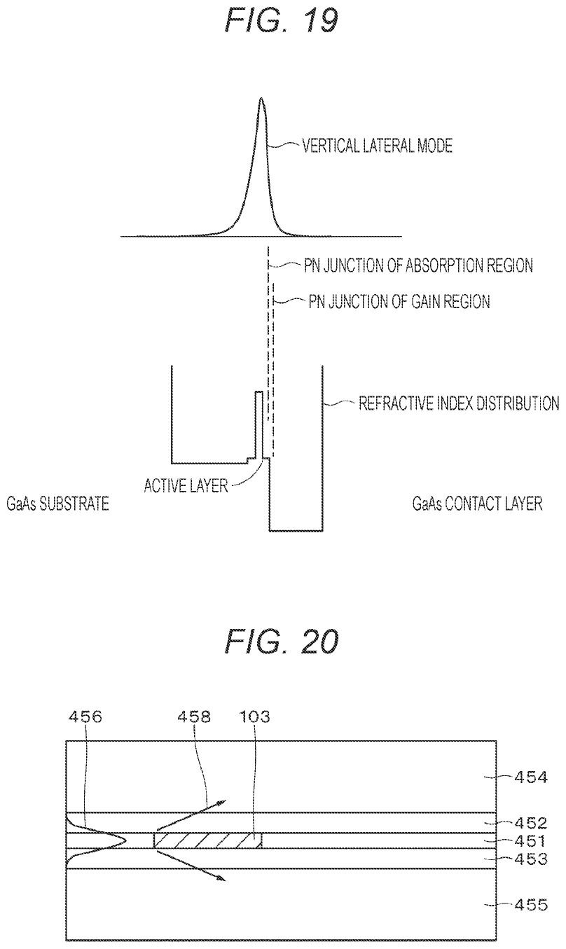

FIG. 19 is a diagram illustrating an example of a layer structure and a lateral mode in the vertical direction of the semiconductor laser 100. As illustrated, a radiation pattern of a laser pulse in the vertical direction can be narrowed by an asymmetric waveguide in which a refractive index of the first cladding layer is significantly larger than that of the second cladding layer.

Light confinement in the vertical direction by the refractive index distribution of the semiconductor layer structure is designed in consideration of propagation from the gain region 102 to the absorption region 103. This point will be described with reference to FIG. 20. An active layer 451 is a refractive index waveguide sandwiched between guide layers 452 and 453 and cladding layers 454 and 455, and there is a fundamental lateral mode 456. In a case where part of the active layer 451 is the absorption region 103, when absorption becomes very large, propagated light is not coupled and is easily scattered to the cladding layer 454455 as indicated by arrows 458. As a result, spontaneous emission light generated in the gain region 102 cannot be efficiently absorbed in the absorption region 103, and stray light in the stacked semiconductor layers causes ASE.

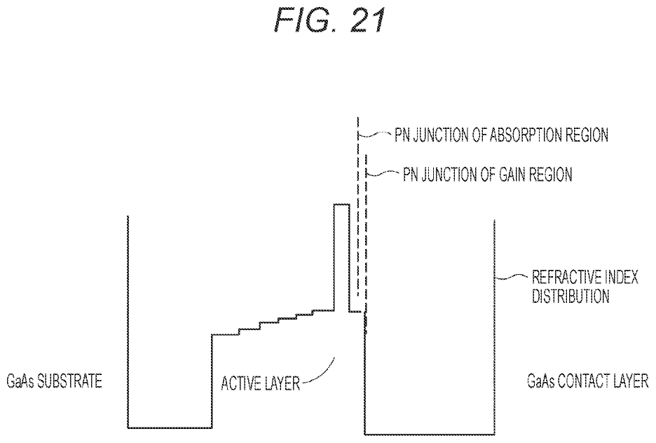

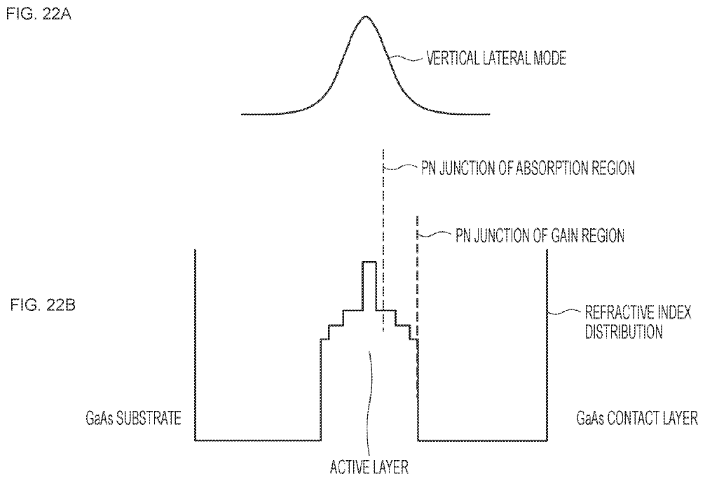

FIG. 21 is an example in which a graded structure is introduced only into the first guide layer 404 (guide layer closer to a side of the semiconductor substrate 401 than the active layer 405). By the first guide layer 404 having a thickness of at least 1 μm or more, most of the lateral mode in the vertical direction on the side of the semiconductor substrate 401 falls within in the first guide layer 404. Even in the absorption region 103 before Q switching, scattering of the propagated light to the cladding layers is suppressed, and the spontaneous emission light generated in the gain region 102 can be efficiently absorbed in the absorption region 103.

FIG. 22 is an example in which the graded structure is introduced into the first guide layer 404 and the second guide layer 406 (guide layers on the side of the semiconductor substrate 401 and on a side of the surface layer, sandwiching the active layer 405). Since a refractive index difference between the guide layer and the cladding layer is large, most of the lateral mode in the vertical direction falls within the first guide layer 404, the active layer 405, and the second guide layer 406. Therefore, even in the absorption region 103 before Q switching, scattering of the propagated light to the cladding layers is suppressed, and the spontaneous emission light generated in the gain region 102 can be efficiently absorbed in the absorption region 103. In such a structure, since a divergence angle of a beam in the vertical direction is likely to be large, each of the first guide layer 404 and the second guide layer 406 is preferably 300 nm or more. With this arrangement, the divergence angle of the beam is narrowed, and coupling efficiency with the collimating lens is improved. A PN junction of the gain region 102 is separated from the active layer 405, and is positioned closer to the side of the surface layer than the PN junction of the absorption region 103 by about 400 nm. This is because the PN junction of the absorption region 103 needs to ensure spatial overlap between the depletion layer and the active layer at the time of a reverse bias, while the PN junction of the gain region 102 needs to suppress overflow of carriers at the time of high current injection. A distance between these PN junctions is preferably at least 100 nm or more. Incidentally, when the PN junction of the gain region 102 is separated from the active layer 405, a laser oscillation delay may become a problem at the time of low current injection, but this does not become a problem at the time of high current injection as in the Q-switched laser.

[Distance Measurement System to which Semiconductor Laser can be Applied]

The semiconductor laser 100 described in the one embodiment can be applied to a distance measurement device. Specific examples of a distance measurement method include the ToF method. The ToF method is classified into several types, and in particular, a direct time-of-flight measurement method (d-ToF) in which a pulsed laser is emitted is subdivided into a linear mode (LM), a Geiger mode (GM), and a single photon (SP) (appropriately referred to as an LM method, a GM method, and an SP method, respectively). In the LM method, a linear light receiving element such as an avalanche photodiode (APD) or the like is used, and the number of photons N with which S/N can be ensured, that is, which is measurable, is about 100 to 1000. In the GM method, photon counting using a single photon avalanche diode (SPAD) or the like is often performed, and an expectation value of the number of received photons in a single shot may be smaller than 1. Histogram processing is performed using the number of received photons N accumulated by a plurality of shots. In the SP method, single shot measurement is performed using a silicon photomultiplier (SiPM) or the like. The number of photons that is measurable is one or more.

### Specific Configuration Example of Distance Measurement System

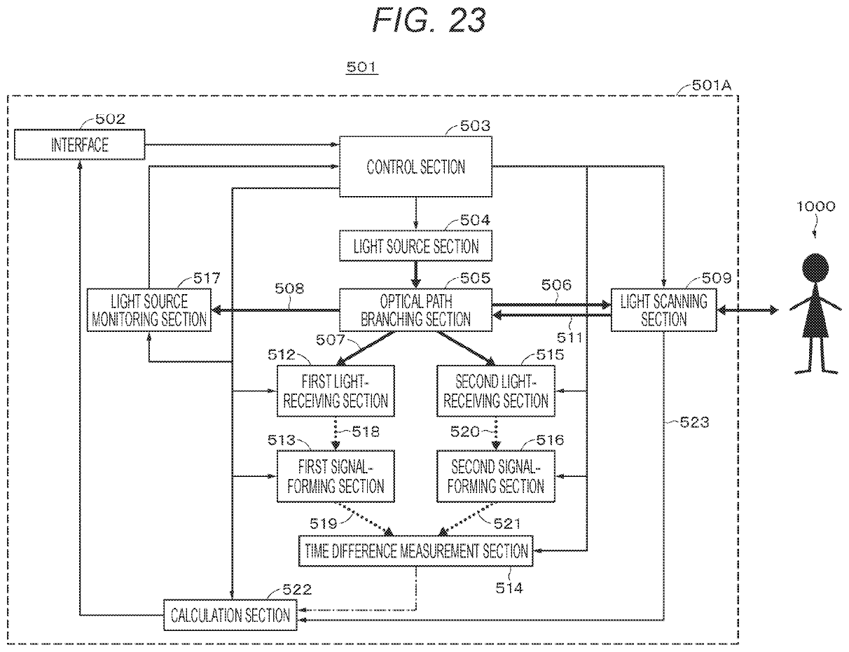

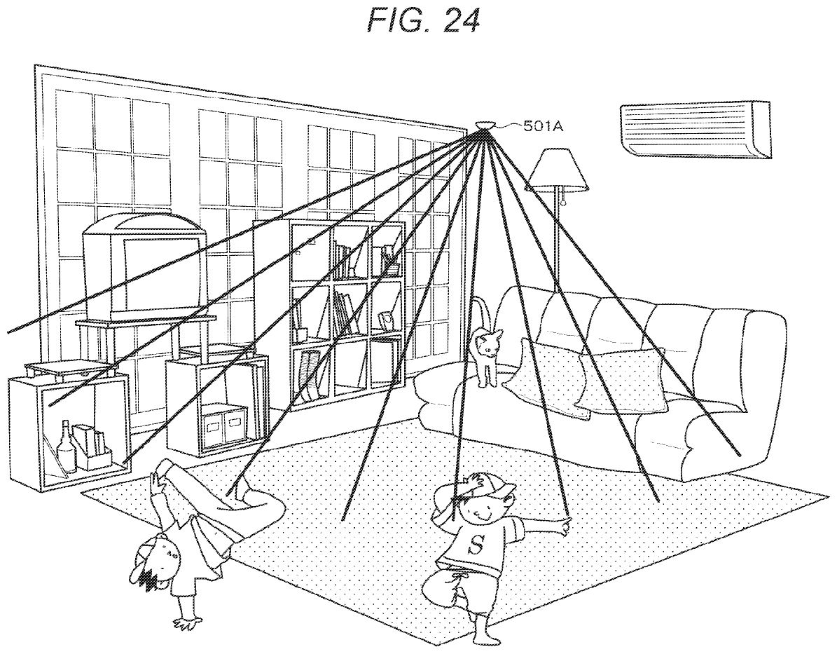

FIG. 23 is a diagram illustrating a specific configuration example of a distance measurement system (distance measurement system 501) in a case where the semiconductor laser 100 described above is applied to the distance measurement system. In FIG. 23, a solid arrow indicates a control signal, a thick arrow indicates an optical path, a broken arrow indicates a signal line, and a dashed-dotted arrow indicates a data line. The distance measurement system 501 includes a distance measurement device 501A and a distance measurement object 1000. The distance measurement device 501A includes an interface 502, a control section 503, a light source section 504 to which the semiconductor laser 100 is applied, an optical path branching section 505, a light scanning section 509, a first light-receiving section 512, a first signal-forming section 513, a time difference measurement section 514, a second light-receiving section 515, a second signal-forming section 516, a light source monitoring section 517, and a calculation section 522.

The interface 502 is an interface used when the distance measurement device 501A and an external device exchange data and commands with each other. The control section 503 integrally controls the entire distance measurement device 501A. Operation of each section of the distance measurement device 501A is controlled by the control section 503.

The control section 503 that has received a control parameter from the outside via the interface 502 transmits a control signal to a plurality of devices and circuits as described later. The light source section 504 includes a Q-switched semiconductor light-emitting element and a driving circuit, has a pulse width of sub-nanoseconds, desirably 20 picoseconds or less, and emits pulsed light with high beam quality having pulse energy of several hundred picojoules to several nanojoules.

In the optical path branching section 505, light from the light source section 504 is branched into measurement light 506 emitted to the distance measurement object 1000 via a beam splitter or the like, reference light 507 for obtaining a start signal of time measurement, and control light 508 for controlling the light source. The measurement light 506 is transmitted to the light scanning section 509, and is sequentially emitted to a designed field of view (FOV) range. The measurement light 506 emitted to the distance measurement object 1000 such as a person or the like is scattered. Part of the scattered light passes through the light scanning section 509 and becomes detection light 511.

The reference light 507 is transmitted to the first light-receiving section 512 and converted into a reference electric signal 518 by a light receiving element such as a photodiode, an avalanche photodiode, an SiPM, or the like. The reference electric signal 518 is transmitted to the time difference measurement section 514 via the first signal-forming section 513. The detection light 511 is transmitted to the second light-receiving section 515 and converted into a detection electric signal 520 by a light receiving element such as the SiPM or the like. The detection electric signal 520 is transmitted to the time difference measurement section 514 via the second signal-forming section 516. As described later, the second signal-forming section 516 amplifies a very weak detection electric signal 520 by single photon detection with high S/N and low jitter.

The first signal-forming section 513 amplifies the reference electric signal 518 that is an analog waveform output from the light receiving element, and generates a reference rectangular wave 519 on the basis of a detection threshold that is arbitrarily set. The second signal-forming section 516 amplifies the detection electric signal 520 that is an analog waveform output from the light receiving element, and generates a detection rectangular wave 521 on the basis of a detection threshold that is arbitrarily set. The control light 508 is transmitted to the light source monitoring section 517, measures pulse energy and a pulse width, and returns information to the control section 503. The number of rectangular waves each transmitted to the time difference measurement section 514 may be one or two or more, and these may be different rectangular waves obtained with two or more detection thresholds. The time difference measurement section 514 uses TDC to measure a relative time of the input rectangular wave. This is a time difference between the reference rectangular wave 519 and the detection rectangular wave 521, or a time difference between a separately prepared clock and the reference rectangular wave or between the clock and the detection rectangular wave. These are different depending on the kind of the TDC. For the TDC, a counter method alone, a method of calculating an average value by performing measurement a plurality of times using the counter method and an inverter-based ring-delay-line, a method of combining the counter method with a highly accurate measurement method having a picosecond resolution, such as vernier buffering or pulse shrink buffering, or the like is used. In addition, the time difference measurement section 514 may have a function of measuring a rise time of the detection electric signal 520 output from the second light-receiving section 515, measuring a peak value, or measuring a pulse integral value. These can be measured by the TDC or an analog to digital converter (ADC).

The time difference measured by the time difference measurement section 514 is transmitted to the calculation section 522. The calculation section 522 performs offset adjustment, performs time-walk error correction using a rise, a peak value, a pulse integral value, and the like of the detection electric signal 520, and performs temperature correction. Then, the calculation section 522 performs vector calculation using scanning timing information 523 transmitted from the light scanning section 509, and obtains a distance to the distance measurement object 1000. Incidentally, distance data and scanning angle data may be output from the interface 502 without performing the vector calculation. In addition, appropriate processing such as noise removal, averaging with adjacent points, interpolation, and the like may be performed on these pieces of data, or advanced algorithms such as recognition processing and the like may be performed thereon.

### Modifications

Although the one embodiment of the present disclosure has been specifically described above, the content of the present disclosure is not limited to the embodiment described above, and various kinds of modifications based on the technical idea of the present disclosure are possible. Hereinafter, modifications will be described.

The items described in each of the embodiment and the modifications can be appropriately combined. In addition, the content of the present disclosure is not to be construed as being limited by the effects exemplified in the present specification.

The present disclosure can also employ the following configurations.

(1)

A semiconductor laser including
at least two or more gain regions and at least two or more absorption regions formed on a semiconductor substrate,
in which the gain regions and the absorption regions include a continuous active layer, and the gain regions and the absorption regions are alternately formed via a separation region, and
from a front end surface, a first laser pulse having a first polarized light is emitted and a second laser pulse having a second polarized light is subsequently emitted, and the first polarized light and the second polarized light are orthogonal to each other.
   (2)

The semiconductor laser according to (1), in which at least two or more of the gain regions having a length of 100 μm or less on a light propagation axis are formed.

(3)

The semiconductor laser according to (1) or (2), in which at least two or more of the absorption regions having a length of 100 μm or less on a light propagation axis are formed.

(4)

The semiconductor laser according to any one of (1) to (3), in which
the gain region in the nearest vicinity of a side of a rear end surface is longer in a resonator direction than another gain regions.
   (5)

The semiconductor laser according to any one of (1) to (4), in which
the active layer is a single layer, and has a thickness in a range of 100 nm to 250 nm.
   (6)

The semiconductor laser according to any one of (1) to (5), in which
a guide layer closer to a side of the semiconductor substrate than the active layer has a graded structure, and has a thickness of at least 1 μm or more.
   (7)

The semiconductor laser according to any one of (1) to (5), in which
guide layers on a side of the semiconductor substrate and a side of a surface layer sandwiching the active layer have a graded structure, and a thickness of at least 300 nm or more.
   (8)

The semiconductor laser according to any one of (1) to (5), in which
guide layers on a side of the semiconductor substrate and on a side of a surface layer sandwiching the active layer have a graded structure, and
a PN junction of the gain region is separated from the active layer than a PN junction of the absorption region by at least 100 nm or more.
   (9)

The semiconductor laser according to any one of (1) to (8), in which
a peak wavelength of the first laser pulse is longer than a peak wavelength of the second laser pulse.
   (10)

The semiconductor laser according to any one of (1) to (9), in which
a peak wavelength of the first laser pulse gradually increases as a time difference is increased at a timing at which a Q-switching operation is induced in the absorption region later than a timing at which a pulse current is applied to the gain region, and hopping of a peak wavelength of at least 1 nm or more occurs.
   (11)

A distance measurement device including:
the semiconductor laser according to (1); and
a light separation unit,
in which the first laser pulse and the second laser pulse are separated by the light separation unit.
   (12)

The distance measurement device according to (11), in which
the first laser pulse includes a laser pulse emitted toward a distance measurement object.
   (13)

The distance measurement device according to (12), further including
a silicon photomultiplier that receives scattered light from the distance measurement object.
   (14)

A vehicle-mounted device including the distance measurement device according to any one of (11) to (13).

### Application Examples

Next, application examples of the present disclosure will be described, but the present disclosure is not limited to the application examples to be described below. The SP method using the semiconductor laser 100 described in the one embodiment can highly efficiently perform distance measurement in a range of dozen centimeters to several tens of meters, and can output distance data with a latency of 1 millisecond or less. Distance accuracy ranges from millimeters to several millimeters, and the following application is possible by utilizing characteristics of low power consumption and small size.

For example, by arranging the distance measurement device 501A using the semiconductor laser 100 of the present disclosure in a corner of a room as illustrated in FIG. 24, the entire room can be measured, and thus, an intense movement in the room or a slight movement such as moving a finger while watching a television on a sofa can be captured. With this arrangement, operation of an electronic device such as a home appliance or the like, gaining of an interactive game experience, and use in security are enabled. Further, in the scanning SP, mutual interference between devices is very small, and thus, 3D modeling can be performed in real time by performing distance measurement from two or more directions with a plurality of distance sensor systems, and a more realistic interactive experience can be provided. Since the SP method can be used even under sunlight, an experience in which a space illustrated in FIG. 24 is expanded to a wider space can be provided.

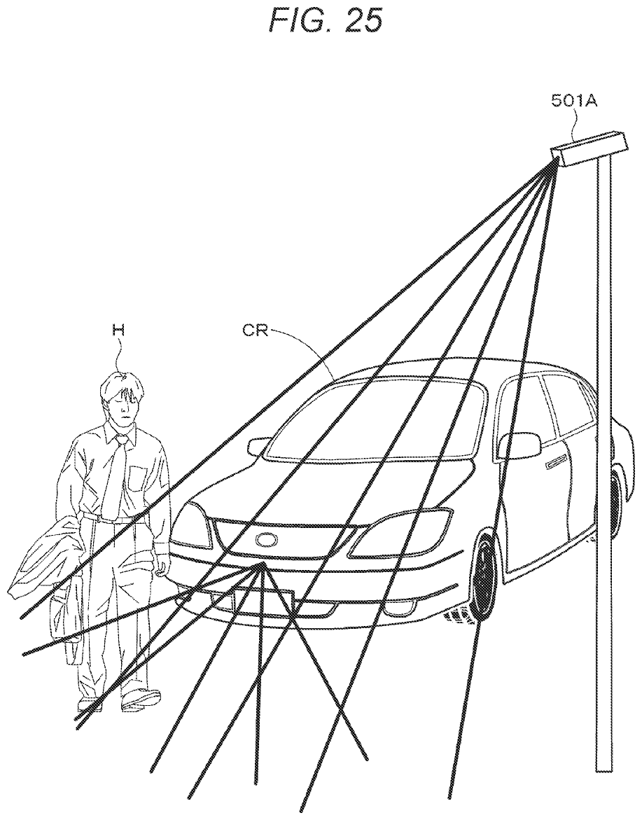

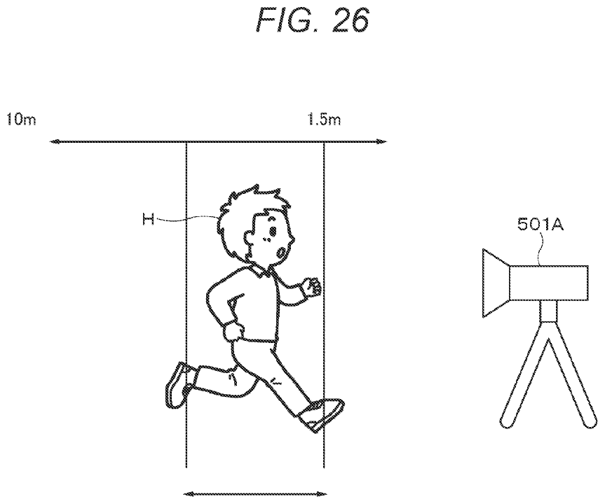

FIG. 25 is a diagram schematically illustrating an application example assuming a use scene in town centered on a person. Since the SP mounted on an automobile CR performs highly accurate distance measurement in real time, even in a case where a distance to a person is short due to being in a narrow place such as an intersection an alley, or the like, even a slight movement can be grasped. With this arrangement, not only safety of a person H but also smooth driving of the automobile CR that performs automated driving can be supported. The SP grounded at a utility pole, at the time of a street, or the like can grasp a slight movement of a person and the like passing without disturbing a moving route of the person H. Obtained data is real-time point cloud data, which allows operation in consideration of privacy. For example, it provides an information service predicting a movement of the person H, detects crimes in advance, or functions as an interface in a case where a person intentionally operates a public object. Such a movement needs to capture the movement of the finger.

FIG. 26 is a diagram schematically illustrating an application example related to an imaging technology. Even in a lens having a very shallow focal depth such as a large camera or the like, by the distance measurement device 501A accurately capturing positional information of a subject (for example, the person H), a focal length and a focal depth can be calculated and adjustment of the lens can be automatically performed. The present disclosure is not limited to this example, and can be used for various devices that automatically control the distance. For example, the present disclosure can also be applied to machine connection, train coupling, aerial refueling of aircraft, artificial satellite connection, and the like.

In addition, since the distance measurement device 501A is small and has low power consumption, the distance measurement device 501A can also be applied to obstacle avoidance of an unmanned airplane such as a drone. There are many severe conditions for the flight of the drone such as a forest, an underground passage, and the like, and the SP that can output the point cloud data in real time enables quick and safe flight. The SP is also excellent in asset management of a structure using a drone, in which a point cloud including mega points or more per second can be obtained in real time, and further, inspection of many structures can be performed in one flight because of its low power consumption.

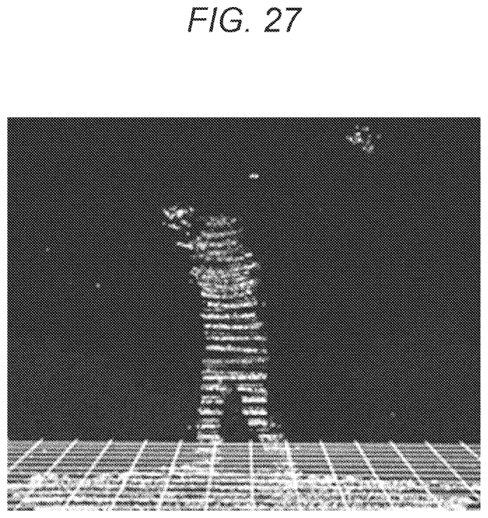

The real-time SP is compatible with sports. In judgement in sports, coaching, and the like, a point cloud of mega points or more per second captures fine movements, and a real-time interactive experience digitizes sports movements that have been sensational. For example, a degree of understanding is increased by a person wearing a wearable device such as a piezoelectric element or the like that can provide bodily sensation and the information obtained by the SP being transmitted to the person in real time. FIG. 27 illustrates an image example of a sport (for example, golf) obtained as described above. A plurality of distance sensors enables real-time 3D modeling from all directions at 360 degrees, and use for swing analysis and teaching in golf, for example, and also use for prevention of injuries and the like are enabled. Since up to a distance of several tens of meters can be covered, the sport is not limited to golf, and use for various sports such as baseball, basketball, tennis, gymnastics, and the like is enabled.

In addition, the technology according to the present disclosure can be applied to various products without being limited to the application examples described above. For example, the technology according to the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, an agricultural machine (tractor), or the like.

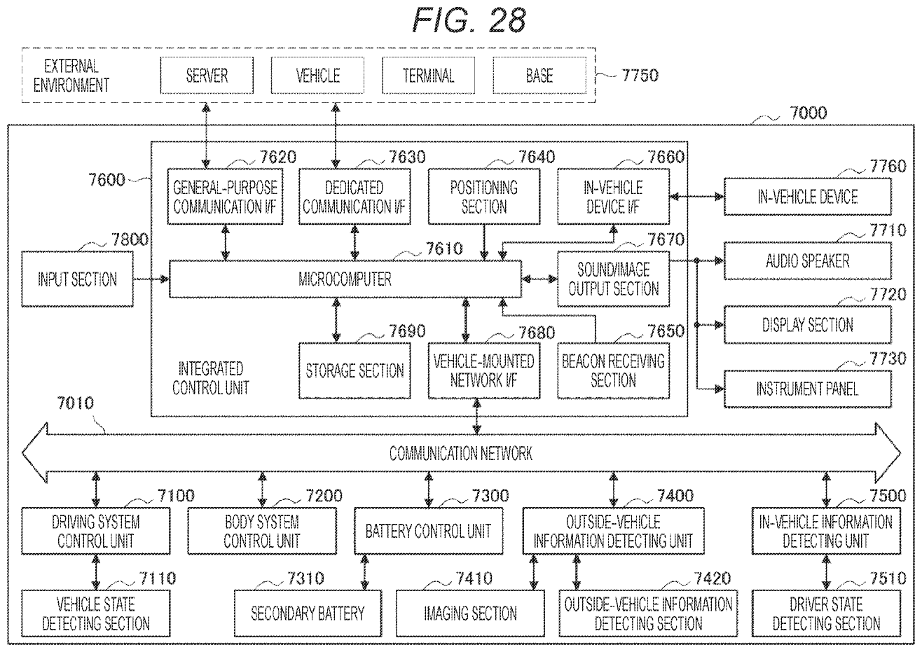

FIG. 28 is a block diagram illustrating a schematic configuration example of a vehicle control system 7000 as an example of a mobile body control system to which the technology according to the present disclosure can be applied. The vehicle control system 7000 includes a plurality of electronic control units connected to each other via a communication network 7010. In the example illustrated in FIG. 28, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each control unit includes a network I/F for communicating with other control units via the communication network 7010, and a communication I/F for communicating with devices, sensors, or the like inside and outside of the vehicle by wired communication or wireless communication. In FIG. 28, a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690 are illustrated as a functional configuration of the integrated control unit 7600. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular speed of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (light detection and ranging device, or laser imaging detection and ranging device). Each of the imaging section 7410 and the outside-vehicle information detecting section 7420 may be provided as an independent sensor or device, or may be provided as a device in which a plurality of sensors or devices are integrated.

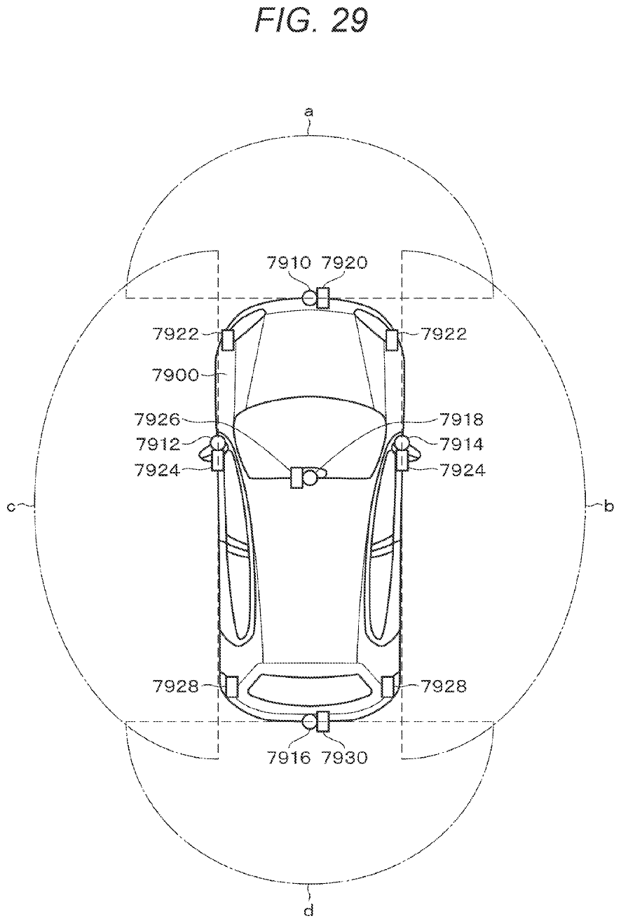

Here, FIG. 29 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 29 illustrates an example of an imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 28, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 28, an audio speaker 7710, a display section 7720, and an instrument panel 7730 are exemplified as the output devices. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, in the example illustrated in FIG. 28, at least two control units connected to each other via the communication network 7010 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

In the vehicle control system 7000 described above, the semiconductor laser of the present disclosure can be applied to, for example, the outside-vehicle information detecting section.

### REFERENCE SIGNS LIST

100 Semiconductor laser
102 Gain region
103 Absorption region
105 First laser pulse
106 Second laser pulse
110 Front end surface
113 Separation region
401 Semiconductor substrate
405 Active layer

1. A semiconductor laser comprising
at least two or more gain regions and at least two or more absorption regions formed on a semiconductor substrate,
wherein the gain regions and the absorption regions include a continuous active layer, and the gain regions and the absorption regions are alternately formed via a separation region, and
from a front end surface, a first laser pulse having a first polarized light is emitted and a second laser pulse having a second polarized light is subsequently emitted, and the first polarized light and the second polarized light are orthogonal to each other.

2. The semiconductor laser according to claim 1, wherein
at least two or more of the gain regions having a length of 100 μm or less on a light propagation axis are formed.

3. The semiconductor laser according to claim 1, wherein
at least two or more of the absorption regions having a length of 100 μm or less on a light propagation axis are formed.

4. The semiconductor laser according to claim 1, wherein
the gain region in a nearest vicinity of a side of a rear end surface is longer in a resonator direction than another gain regions.

5. The semiconductor laser according to claim 1, wherein
the active layer is a single layer, and has a thickness in a range of 100 nm to 250 nm.

6. The semiconductor laser according to claim 1, wherein
a guide layer closer to a side of the semiconductor substrate than the active layer has a graded structure, and has a thickness of at least 1 μm or more.

7. The semiconductor laser according to claim 1, wherein
guide layers on a side of the semiconductor substrate and a side of a surface layer sandwiching the active layer have a graded structure, and a thickness of at least 300 nm or more.

8. The semiconductor laser according to claim 1, wherein
guide layers on a side of the semiconductor substrate and on a side of a surface layer sandwiching the active layer have a graded structure, and
a PN junction of the gain region is separated from the active layer than a PN junction of the absorption region by at least 100 nm or more.

9. The semiconductor laser according to claim 1, wherein
a peak wavelength of the first laser pulse is longer than a peak wavelength of the second laser pulse.

10. The semiconductor laser according to claim 1, wherein
a peak wavelength of the first laser pulse gradually increases as a time difference is increased at a timing at which a Q-switching operation is induced in the absorption region later than a timing at which a pulse current is applied to the gain region, and hopping of a peak wavelength of at least 1 nm or more occurs.

11. A distance measurement device comprising:
the semiconductor laser according to claim 1; and
a light separation unit,
wherein the first laser pulse and the second laser pulse are separated by the light separation unit.

12. The distance measurement device according to claim 11, wherein
the first laser pulse includes a laser pulse emitted toward a distance measurement object.

13. The distance measurement device according to claim 12, further comprising
a silicon photomultiplier that receives scattered light from the distance measurement object.

14. A vehicle-mounted device comprising the distance measurement device according to claim 11.
